(19) United States
(12) Patent Application Publication
(10) Pub. No.: US 2016/0313618 A1
(43) Pub. Date: Oct. 27, 2016

(54) LIQUID CRYSTAL DISPLAY DEVICE AND MANUFACTURING METHOD THEREOF

(71) Applicant: Samsung Display Co., Ltd., Yongin-si (KR)

(72) Inventors: Jungsoo LEE, Seoul (KR); Jeongmin PARK, Seoul (KR); Jihyun KIM, Suwon-si (KR); Junhong PARK, Yongin-si (KR)

(21) Appl. No.: 15/046,662

(22) Filed: Feb. 18, 2016

(30) Foreign Application Priority Data
Apr. 22, 2015 (KR) 10-2015-0056706

(51) Int. Cl. G02F 1/1362; G02F 1/1333; H01L 27/12; G02F 1/1368

(52) U.S. Cl. CPC G02F 1/136227; G02F 1/1368; G02F 1/136286; G02F 1/133345; H01L 27/1288; G02F 2001/136222; G02F 2001/136295

(57) ABSTRACT

A liquid crystal display device includes: a liquid crystal layer between first and second display panels. Then first display panel includes:gate and data lines on a first substrate; a thin film transistor connected to the gate and data lines and exposed at a single contact hole; a color filter on the thin film transistor; a first insulation layer covering the color filter and in which is defined a first contact hole exposing the thin film transistor at the single contact hole; common and pixel electrodes on the first insulation layer and overlapping each other; and a second insulation layer between the pixel and common electrodes and in which is defined a second contact hole exposing the thin film transistor at the single contact hole. Shapes of the first and second contact holes correspond to each other to define the single contact hole at which the thin film transistor is exposed.

This application claims priority to Korean Patent Application No. 10-2015-0056706, filed on Apr. 22, 2015, and all the benefits accruing therefrom under 35 U.S.C. §119, the disclosure of which is incorporated herein in its entirety by reference.

### BACKGROUND

1. Field

Exemplary embodiments of the invention relate to a liquid crystal display (“LCD”) device for which a process of defining a contact hole therein is simplified and image resolution is enhanced, and to a method of manufacturing the LCD device.

2. Description of the Related Art

An LCD device includes two transparent display substrates (e.g., display panels) and a liquid crystal layer interposed therebetween. The liquid crystal layer may be operated to adjust a level of light transmittance therethrough for each pixel of the LCD device, such that the LCD device may display a desired image.

The most prevalently employed structure of the LCD device may include an electric-field generating electrode disposed in each of the two display panels. For example, the LCD device may have a structure in which a plurality of thin film transistors and a pixel electrode are arranged on a base substrate of a thin film transistor display panel in a matrix form; and red, green and blue color filters are disposed on a base substrate of a color filter display panel. The LCD device may further include a common electrode which covers an entire surface in one of the display panels.

However, since the pixel electrode and the color filter are disposed in different display panels in such an LCD device, correctly aligning the pixel electrode and the color filter may be difficult, and thus an alignment error therebetwen may occur.

### SUMMARY

Exemplary embodiments of the invention are directed to a liquid crystal display (“LCD”) device for which a process of defining a contact hole in a color filter or in insulation layer covering the color filter is simplified and image resolution of the LCD device is enhanced, and to a method of manufacturing the LCD device.

According to an exemplary embodiment of the invention, an LCD device includes: a first display panel and a second display panel facing each other, and a liquid crystal layer between the first and second display panels facing each other. The first display panel includes: a first substrate; a gate line and a data line on the first substrate; a thin film transistor connected to the gate line and the data line, a terminal of the thin film transistor exposed at a single contact hole; a color filter on the thin film transistor; a first insulation layer covering the color filter to dispose the color filter between the first insulation layer and the thin film transistor, the first insulation layer including defined therein a first contact hole which exposes the terminal of the thin film transistor at the single contact hole; a common electrode on the first insulation layer covering the color filter; a pixel electrode on the first insulation layer covering the color filter, the pixel electrode overlapping the common electrode; and a second insulation layer between the pixel electrode and the common electrode, the second insulation layer including defined therein a second contact hole which exposes the terminal of the thin film transistor at the single contact hole. A shape of the first contact hole may correspond to a shape of the second contact hole to define the single contact hole at which the terminal of the thin film transistor is exposed.

The terminal of the thin film transistor may include a drain electrode, and the first contact hole and the second contact hole at the single contact hole may expose the drain electrode.

The pixel electrode may be connected to the drain electrode at the first contact hole and the second contact hole of which the shapes thereof correspond to define the single contact hole at which the terminal of the thin film transistor is exposed.

An inclined surface of the first insulation layer at the first contact hole and an inclined surface of the second insulation layer at the second contact hole define the single contact hole at which the terminal of the thin film transistor is exposed. In a top plan view of the single contact hole, the second insulation layer at the single contact hole may not overlap the inclined surface of the first insulation layer at the first contact hole.

The LCD device may further include a third insulation layer between the data line and the color filter, the third insulation layer including defined therein a third contact hole which exposes the terminal of the thin film transistor at the single contact hole.

An inclined surface of the first insulation layer at the first contact hole, an inclined surface of the second insulation layer at the second contact hole and an inclined surface of the third insulation layer at the third contact hole define the single contact hole at which the terminal of the thin film transistor is exposed. In a top plan view of the single contact hole, the second insulation layer at the single contact hole may not overlap the inclined surface of the third insulation layer at the third contact hole.

According to another exemplary embodiment of the invention, a method of manufacturing an LCD device includes: providing a first display panel and a second display panel to face each other, and providing a liquid crystal layer between the first and second display panels facing each other. The providing the first display panel includes: forming a gate line, a data line, and a thin film transistor which is connected to the gate line and the data line on a first substrate a terminal of the thin film transistor exposed at a single contact hole; forming a color filter on the gate line, on the data line and on the thin film transistor; forming a first insulation layer covering the color filter to dispose the color filter between the first insulation layer and the thin film transistor; forming a common electrode on the first insulation layer covering the color filter; forming a second insulation layer on the common electrode to dispose the common electrode between the first and second insulation layers; and forming a first contact hole and a second contact hole respectively in the first insulation layer and in the second insulation layer, simultaneously, to define the single contact hole at which the terminal of the thin film transistor is exposed.

The forming the first contact hole and the second contact hole may include: coating a photoresist on the second insulation layer which disposes the common electrode between the first and second insulation layers; performing light exposure on the photoresist using a mask; developing the light-exposed photoresist to form a photoresist pattern; and simultaneously etching the first insulation layer and the second insulation layer between which is the common electrode using the photoresist pattern to simultaneously form the first contact hole and the second contact hole in the first insulation layer and in the second insulation layer, respectively, to define the single contact hole at which the terminal of the thin film transistor is exposed.

The method may further include forming a pixel electrode on the second insulation layer to dispose the second insulation layer between the pixel electrode and the common electrode.

The terminal of the thin film transistor may include a drain electrode.

The first contact hole and the second contact hole at the single contact hole may expose the drain electrode.

The pixel electrode may be connected to the drain electrode at the first contact hole and the second contact hole of which shapes thereof correspond to define the single contact hole at which the terminal of the thin film transistor is exposed.

According to another exemplary embodiment of the invention, a method of manufacturing an LCD device includes: providing a first display panel and a second display panel to face each other, and providing a liquid crystal layer between the first and second display panels facing each other. The providing the first display panel includes: forming a gate line, a data line, and a thin film transistor connected to the gate line and the data line on a first substrate, a terminal of the thin film transistor exposed at a single contact hole; forming a third insulation layer on the gate line, the data line, and the thin film transistor to dispose the gate line, the data line and the thin film transistor between the third insulation layer and the first substrate; forming a color filter on the gate line, the data line, and the thin film transistor to dispose the third insulation layer between the color filter and the thin film transistor; forming a first insulation layer covering the color filter to dispose the color filter between the first insulation layer and the third insulation layer; forming a common electrode on the first insulation layer covering the color filter; forming a second insulation layer on the common electrode to dispose the common electrode between the first and second insulation layers; and forming a first contact hole, a second contact hole and a third contact hole respectively in the first insulation layer, in the second insulation layer and in the third insulation layer, simultaneously to define the single contact hole at which the terminal of the thin film transistor is exposed.

The forming the first contact hole, the second contact hole and the third contact hole may include: coating a photoresist on the second insulation layer which disposes the common electrode between the first and second insulation layers; performing light exposure on the photoresist using a mask; developing the light-exposed photoresist to form a photoresist pattern; and simultaneosly etching the first insulation layer, the second insulation layer and the third insulation layer using the photoresist pattern to simultaneously form the first contact hole, the second contact hole and the third contact hole in the first insulation layer, in the second insulation layer and in the third insulation layer, respectively, to define the single contact hole at which the terminal of the thin film transistor is exposed.

According to exemplary embodiments of the invention, an additional separate light exposure process for an existing insulation layer covering a color filter may be omitted, and thus efficiency of a process of forming a liquid crystal display device may be enhanced. Further, a photoresist disposed after the existing insulation layer is formed may not remain within the contact hole defined in the existing insulation layer, and thereby a display device including the insulation layer may realize relatively high image resolution.

Further, contact holes respectively being formed in a first insulation layer covering the color filter and in a second insulation layer insulating a pixel electrode from a common electrode, may be correctly aligned with each other, such that the display device may realize relatively high image resolution.

### BRIEF DESCRIPTION OF THE DRAWINGS

The above and other features of the invention will be more clearly understood from the following detailed description taken in conjunction with the accompanying drawings, in which:

FIG. 1 is a plan view illustrating an exemplary embodiment of a liquid crystal display (“LCD”) device according to the invention;

FIG. 2 is a cross-sectional view taken along line I-I′ of FIG. 1;

FIGS. 3A through 3G are cross-sectional views illustrating an exemplary embodiment of a method of manufacturing an LCD device according to the invention.

### DETAILED DESCRIPTION

Advantages and features of the invention and methods for achieving them will be made clear from exemplary embodiments described below in detail with reference to the accompanying drawings. The invention may, however, be embodied in many different forms and should not be construed as being limited to the exemplary embodiments set forth herein. Rather, these exemplary embodiments are provided so that this disclosure will be thorough and complete, and will fully convey the scope of the invention to those skilled in the art. The invention is merely defined by the scope of the claims. Therefore, well-known constituent elements, operations and techniques are not described in detail in the exemplary embodiments in order to prevent the invention from being obscurely interpreted. Like reference numerals refer to like elements throughout the specification.

The spatially relative terms “below,” “beneath,” “lower,” “above,” “upper” and the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device shown in the drawing is turned over, the device positioned “below” or “beneath” another device may be placed “above” another device. Accordingly, the illustrative term “below” may include both the lower and upper positions. The device may also be oriented in the other direction, and thus the spatially relative terms may be interpreted differently depending on the orientations.

Throughout the specification, when an element is referred to as being “connected” to another element, the element is “physically connected” to the other element or “electrically connected” to the other element with one or more intervening elements interposed therebetween. When an element is referred to as being “directly connected” to another element, the element is “directly physically connected” to the other element or “directly electrically connected” to the other element with no intervening elements interposed therebetween.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

A color filter on array (“COA”) structure has been suggested so as to mitigate misalignment of the pixel electrode and the color filter. In the COA structure, the color filter and the pixel electrode are disposed within a same display panel. Where the color filter and the pixel electrode are disposed within a same display panel, a contact hole may be defined in the color filter or in an insulation layer covering the color filter to allow the pixel electrode and the thin film transistor in different layers of the display panel to be in contact with each other. In this regard, a dry etching process may be performed to define the contact hole in the color filter or in the insulation layer, but the process is quite difficult to perform.

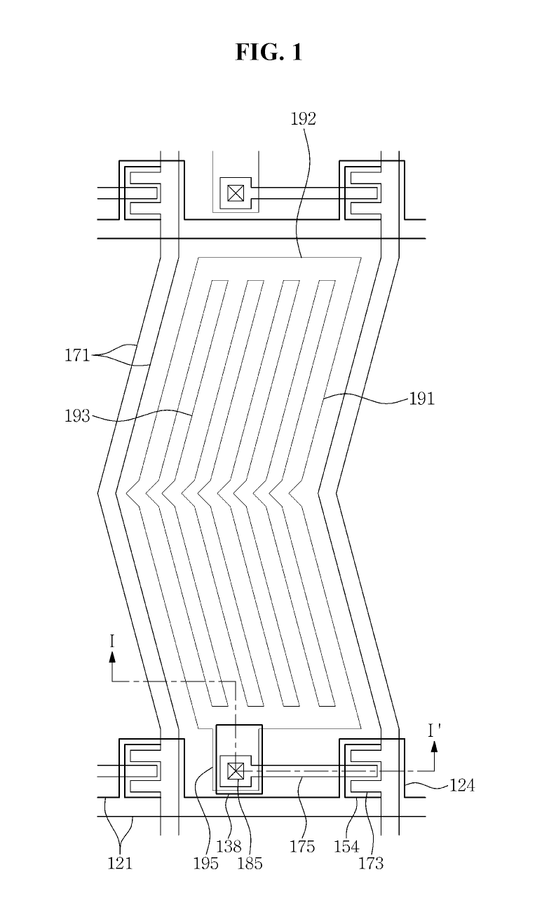

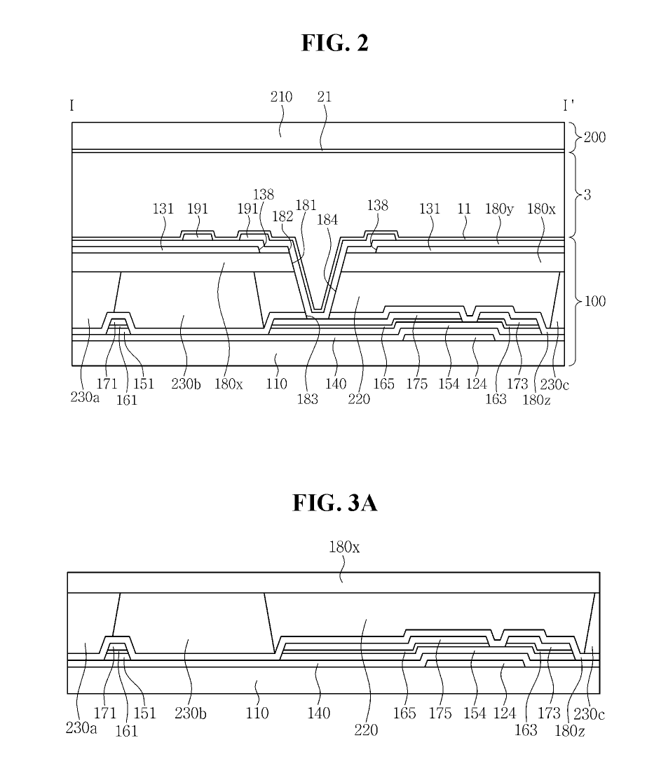

Hereinafter, an exemplary embodiment of a liquid crystal display (“LCD”) device according to the invention will be described with reference to FIGS. 1 and 2.

FIG. 1 is a plan view illustrating an exemplary embodiment of an LCD device according to the invention; and FIG. 2 is a cross-sectional view taken along line I-I′ of FIG. 1.

The LCD device includes a lower display panel 100 and an upper display panel 200 opposing each other, and a liquid crystal layer 3 interposed therebetween.

Hereinafter, descriptions pertaining to the lower display panel 100 will be described.

A gate conductor including a plurality of gate lines 121 may be disposed on a first substrate 110.

The gate line 121 may transmit a gate signal and a length thereof may primarily extend in a (first) transverse direction in the plan view. Each of the gate lines 121 may define a plurality of gate electrodes 124 protruded from a main portion thereof

A gate insulation layer 140 may be disposed on the gate line 121. The gate insulation layer 140 may include or be formed of an inorganic insulating material such as silicon nitride (SiNₓ) or silicon oxide (SiOₓ).

A plurality of semiconductors 151 may be disposed on the gate insulation layer 140. Each of the semiconductors 151 may define a plurality of semiconductor protrusions 154 extending from a main portion thereof and along the gate electrode 124. Further, the semiconductor protrusion 154 may only be disposed on the gate electrode 124.

The semiconductor 151 may include amorphous silicon, polycrystalline silicon or an oxide semiconductor. The oxide semiconductor may include one or more of the following materials: zinc (Zn), gallium (Ga), indium (In), and tin (Sn).

In an exemplary embodiment, the oxide semiconductor may include or be formed of an oxide semiconductor material, for example, Zn, Ga, Sn or In based oxide, or composite oxide such as zinc oxide (ZnO), indium-gallium-zinc oxide (InGaZnO₄), indium-zinc oxide (In-Zn-O), or zinc-tin oxide (Zn-Sn-O).

In detail, the oxide semiconductor may include IGZO-based oxide including In, Ga, Zn and oxygen (0). Further, the oxide semiconductor may include In-Sn-Zn-O based metal oxide, In-Al-Zn-O based metal oxide, Sn-Ga-Zn-O based metal oxide, Al-Ga-Zn-O based metal oxide, Sn-Al-Zn-O based metal oxide, In-Zn-O based metal oxide, Sn-Zn-O based metal oxide, Al-Zn-O based metal oxide, In-O based metal oxide, Sn-O based metal oxide, and Zn-O based metal oxide.

A plurality of ohmic contact members 161, 163 and 165 may be disposed on the semiconductors 151 and the semiconductor protrusions 154. The ohmic contact members 163 and 165 may be disposed on the semiconductor 151 in pairs, such as opposing each other on the semiconductor 151 with respect to the gate electrode 124.

The ohmic contact members 161, 163 and 165 may include silicide or n+ hydrogenated amorphous silicon doped with n-type impurities, such as phosphorus (P), at a relatively high concentration.

A data conductor including a plurality of data lines 171 and a plurality of drain electrodes 175 may be disposed on the ohmic contact members 161, 163 and 165.

The data lines 171 may transmit a data signal and a length thereof may primarily extend in a (second) longitudinal direction in the top plan view to intersect the gate lines 121. Each of the data lines 171 may define a plurality of source electrodes 173 extending from a main portion thereof toward the gate electrode 124. Along the length thereof, the data line 171 may be bent periodically, and inclined portions thereof may form an oblique angle with a direction in which the length of the gate line 121 extends. An angle between portions of the data line 171 and the direction in which the length of the gate line 121 extends may be about 45 degrees or more.

The drain electrode 175 may have a bar-shaped first end portion opposing the source electrode 173 and a second end portion having a relatively greater planar area than that of other portions thereof. The first and second ends of the drain electrode 175 may oppose each other with respect to the gate electrode 124.

The gate electrode 124, the source electrode 173 and the drain electrode 175 spaced apart from the source electrode 173 may constitute a thin film transistor (“TFT”), which is a switching element, along with a semiconductor protrusion 154 which is exposed by the spaced apart source and drain electrodes 173 and 175. The semiconductor 151 may be considered a linear semiconductor except for the semiconductor protrusion 154. The linear semiconductor 151 may have a shape, for example, a planar surface shape, substantially the same as that of the data line 171, the drain electrode 175, and the ohmic contact members 161, 163 and 165 which are disposed therebelow.

A third insulation layer 180z may be disposed on the data conductor, for example, the data line 171 and the drain electrode 175, and the semiconductor protrusion 154 which is exposed by the spaced apart source and drain electrodes 173 and 175. The third insulation layer 180z may include an organic insulating material or an inorganic insulating material.

Referring to FIG. 2, a light blocking member 220, which is also referred to as a black matrix, may be disposed on a portion of the third insulation layer 180z corresponding to the gate line 121, the data line 171 and the thin film transistor. A plurality of color filters 230a, 230b and 230c may be disposed in a pixel region partitioned by the light blocking member 220. Each of the color filters 230a, 230b and 230c may individually display one of primary colors, for example, three primary colors of red, green and blue; or yellow, cyan and magenta. Although not illustrated, among the color filters in pixel regions partitioned by the light blocking member 220, a color filter may further be provided to display a mixed color of the primary colors or a white color, rather than individually displaying one of the primary colors. The color filters 230a, 230b and 230c may include or be formed of an organic material.

A first insulation layer 180x may be disposed on the color filters 230a, 230b and 230c and on the light blocking member 220. The first insulation layer 180x may include an organic material, and may have a planar surface. The first insulation layer 180x may reduce a step difference between the respective color filters 230a, 230b, and 230c disposed in adjacent pixels to allow a first alignment layer 11 to be uniformly rubbed.

However, the first insulation layer 180x may be an inorganic insulation layer, and may reduce or effectively prevent exposure of a component of the color filters 230a, 230b and 230c outwards into other layers of the lower display panel 100 among layers on the first substrate 110. In an exemplary embodiment of manufacturing a display device, the first insulation layer 180x may be formed at a temperature less than a temperature at which the gate insulation layer 140 is formed to thereby reduce or effectively prevent deformation or discoloration of the color filters 230a, 230b and 230c disposed therebelow. Further, the first insulation layer 180x may reduce a loss in transmittance that is caused due to a difference between refractive indices of the color filters 230a, 230b and 230c and the third insulation layer 180z disposed therebelow.

In an alternative exemplary embodiment, the light blocking member 220 may be omitted from the lower display panel 100. Further, in the top plan view, each of the color filters 230a, 230b and 230c may have a length which extends in the second direction along the data line 171, and two of the color filters adjacently disposed in the first direction with respect to the data line 171, for example, the color filters 230a and 230b and/or the color filters 230b and 230c, may overlap each other along the first direction. In other words, for the alternative exemplary embodiment, instead of the light blocking member 220 being disposed on a portion of the third insulation layer 180z corresponding to the gate line 121, the data line 171 and the thin film transistor, each of the color filters 230a, 230b and 230c may be disposed on a portion of the third insulation layer 180z, corresponding to the gate line 121, the data line 171 and the thin film transistor.

In some embodiments, each of the color filters 230a, 230b, and 230c may only be disposed in the pixel region and not at the gate line 121, the data line 171, and the thin film transistor, and the first insulation layer 180x covering each of the color filters 230a, 230b and 230c may be disposed in a portion corresponding to the gate line 121, the data line 171 and the thin film transistor at which the color filters are not disposed. In other words, the first insulation layer 180x may be disposed between the respective color filters 230a, 230b and 230c which are disposed only in the pixel region.

A plurality of common electrodes 131 may be disposed on the first insulation layer 180x. The common electrode 131 may include or be formed of a transparent conductive material, such as indium tin oxide (“ITO”) or indium zinc oxide (“IZO”). The common electrode 131 may have a surface shape disposed to be extended on an entire surface of the first substrate 110 as a single panel. An aperture 138 is defined in the common electrode 131 at an area corresponding to a portion of the drain electrode 175 and the aperture 138 may surround the portion of the drain electrode 175.

A second insulation layer 180y may be disposed on the common electrode 131. The second insulation layer 180y may include an organic insulating material or an inorganic insulating material.

A pixel electrode 191 may be disposed on the second insulation layer 180y. The pixel electrode 191 may define a plurality of branch electrodes 193 primarily extending parallel to each other and spaced apart from each other, and upper and lower transverse portions 192 connecting upper and lower ends of the plurality of branch electrodes 193, respectively. The branch electrode 193 of the pixel electrode 191 may be bent along a shape of the data line 171. Further, the pixel electrode 191 may define a pixel electrode protrusion 195 extending in a direction in which the drain electrode 175 is disposed. The pixel electrode protrusion 195 may be in direct contact with the drain electrode 175. The pixel electrode 191 may include or be formed of a transparent conductive material such as indium tin oxide (“ITO”) or indium zinc oxide (“IZO”).

A third contact hole 183, a fourth contact hole 184, a first contact hole 181 and a second contact hole 182, which expose a portion of the drain electrode 175, may be defined in the third insulation layer 180z, the light blocking member 220, the first insulation layer 180x and the second insulation layer 180y, respectively. The first through fourth contact holes 181, 182, 183 and 184 defined a single contact hole 185 (refer to FIG. 1). The pixel electrode 191 may be electrically connected to the drain electrode 175 at the first through fourth contact holes 181, 182, 183 and 184 to receive a data voltage from the drain electrode 175. The pixel electrode protrusion 195 is in contact with the drain electrode at the first through fourth contact holes 181, 182, 183 and 184.

In other words, the first insulation layer 180x may have the first contact hole 181 defined therein, the second insulation layer 180y may have the second contact hole 182 defined therein, the third insulation layer 180z may have the third contact hole 183 defined therein, and the light blocking member 220 may have the fourth contact hole 184 defined therein.

The first, second, third and fourth contact holes 181, 182, 183 and 184 may be defined at an area corresponding to the aperture 138 defined in the common electrode 131. The first, second, third and fourth contact holes 181, 182, 183 and 184 may have shapes corresponding to each other. The first through fourth contact holes 181, 182, 183 and 184 are aligned with each other to form a continuous single contact hole 185. Inclined surfaces of the first insulation layer 180x, the second insulation layer 180y, the third insulation layer 180z and the light blocking member 220 at the continuous single contact hole 185 may extend in a same direction such that the inclined surfaces are coplanar with each other to define the single contact hole 185.

In the top plan view of the single contact hole 185, the second insulation layer 180y may not overlap an inclined surface of the first insulation layer 180x at the first contact hole 181, an inclined surface of the third insulation layer 180z at the third contact hole 183, and an inclined surface of the light blocking member 220 at the fourth contact hole 184.

The pixel electrode 191 that receives the data voltage from the drain electrode 175 may generate an electric field in the liquid crystal layer 3, along with the common electrode 131 that receives a common voltage.

The branch electrode 193 of the pixel electrode 191 may overlap the common electrode 131, which has a surface shape.

In the LCD device according to the exemplary embodiment, the common electrode 131 may commonly cover the plurality of data lines 171 to overlap the data lines 171. Accordingly, cross-talk between the data lines 171 and the pixel electrode 191 may be mitigated. Further, light leakage caused by a parasitic capacitance between the data lines 171 and the pixel electrode 191 disposed adjacent thereto may be reduced.

The first alignment layer 11 may be disposed over an inner surface of the lower display panel 100.

Hereinafter, descriptions pertaining to the upper display panel 200 will be described.

A second alignment layer 21 may be disposed over a second substrate 210.

The first alignment layer 11 and the second alignment layer 21 may be a homeotropic alignment layer, but the invention is not limited thereto.

The liquid crystal layer 3 interposed between the lower display panel 100 and the upper display panel 200 may include liquid crystal molecules (not illustrated). A major axis of the liquid crystal molecules may be aligned to be horizontal (e.g., parallel) with respect to surfaces of the lower display panel 100 and the upper display panel 200, in a state where an electric field is absent.

The liquid crystal layer 3 may have positive dielectric anisotropy, or may have negative dielectric anisotropy. The liquid crystal molecules of the liquid crystal layer 3 may be pre-aligned to have a pretilt in a predetermined direction, and the pretilt direction of the liquid crystal molecules may vary based on the dielectric anisotropy of the liquid crystal layer 3.

A backlight unit (not illustrated) may further be provided outside of the first substrate 110 of the lower display panel 100 to generate light and provide the generated light to the lower display panel 100 and the upper display panel 200.

The pixel electrode 191 that receives the data voltage, along with the common electrode 131 that receives the common voltage, may generate an electric field in the liquid crystal layer 3, and thus may determine a direction of the liquid crystal molecules of the liquid crystal layer 3 and display a corresponding image.

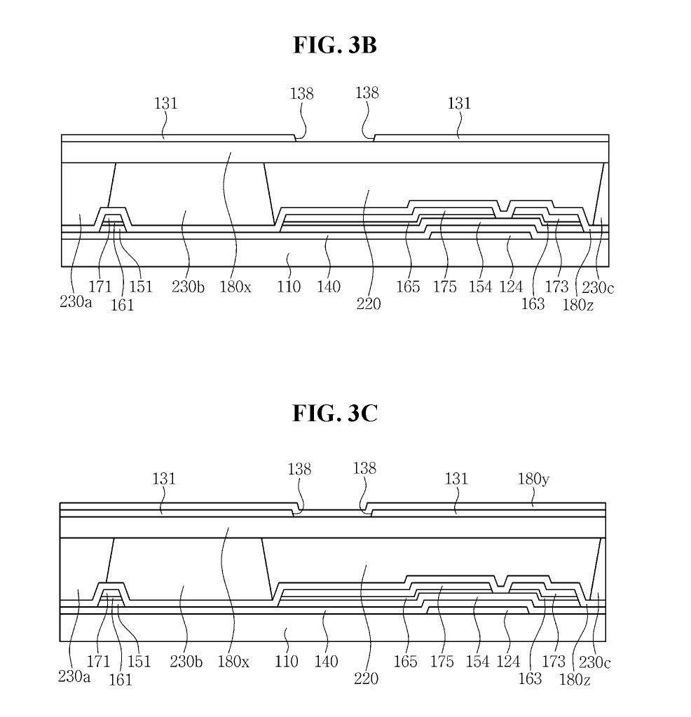

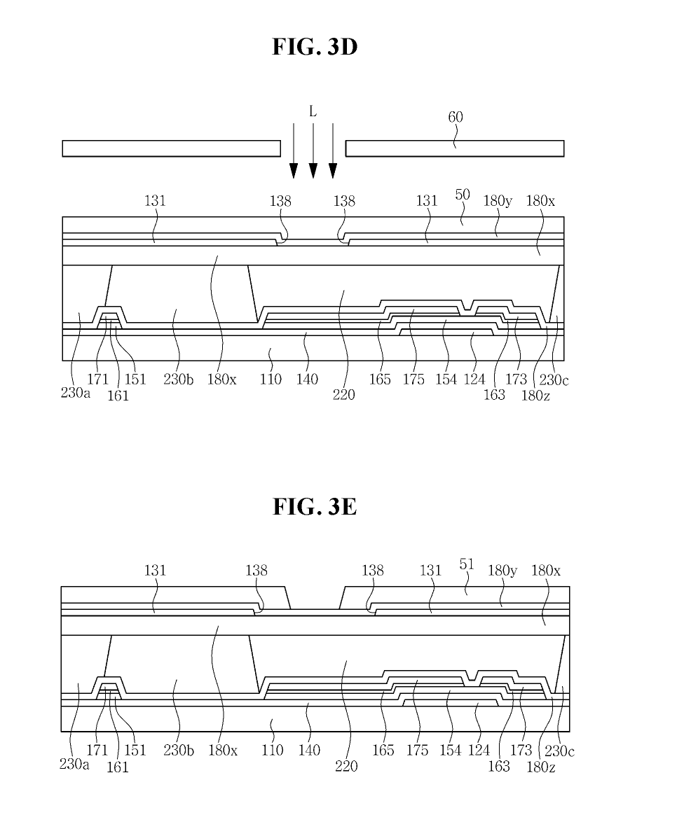

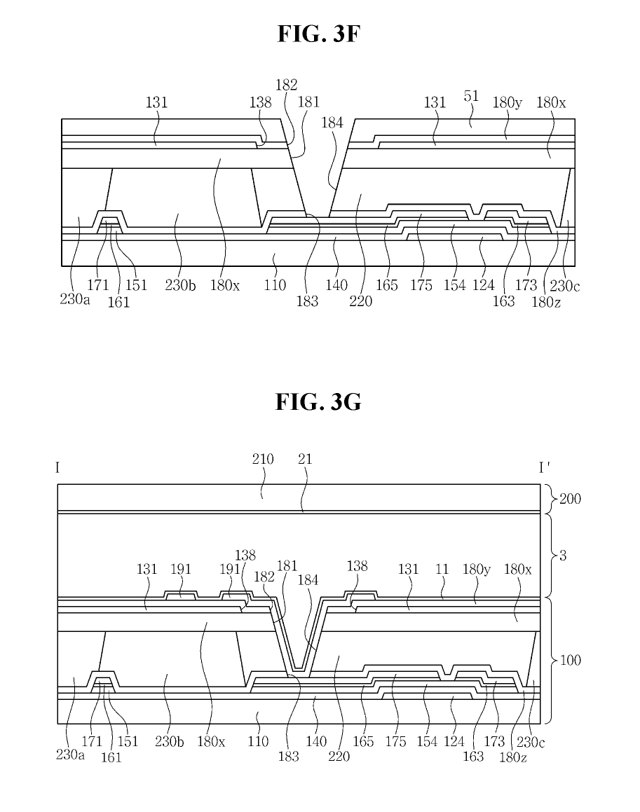

Hereinafter, an exemplary embodiment of a method of manufacturing a lower display panel of an LCD device will be described with reference to FIGS. 3A through 3G.

FIGS. 3A through 3G are cross-sectional views illustrating an exemplary embodiment of a method of manufacturing an LCD device according to the invention.

As illustrated in FIG. 3A, a gate line 121, a data line 171, a thin film transistor, a third insulation layer 180z, a light blocking member 220, color filters 230a, 230b and 230c, and a first insulation layer 180x may be formed on a first substrate 110.

The first substrate 110 may include or be formed of a transparent material, such as glass or plastic, and the thin film transistor may be connected to the gate line 121 and the data line 171. Although the aforementioned elements are described as simply being formed on the first substrate 110 in FIG. 3A, a plurality of processes may be performed to form the elements of the structure. Hereinafter, the processes will be described by way of example, but the invention is not limited thereto.

The gate line 121 and a gate electrode 124 which is defined by the gate line may be formed on the first substrate 110, and a gate insulation layer 140 may then be formed to cover the gate line 121 and the gate electrode 124.

A data line 171 and a source electrode 173 defined by the data line 171 may be formed on the gate insulation layer 140 to be extended in a direction to intersect the gate line 121, and a drain electrode 175 which is an output terminal of the thin film transistor may also be formed. The data line 171 and the drain electrode 175 may be formed in a same layer of the lower display panel 100 among layers formed on the first substrate 110.

In an exemplary embodiment, ohmic contact members 161, 163 and 165 and semiconductors 151 which define semiconductor protrusions 154 may be formed between the data line 171 and the gate insulation layer 140 and between the drain electrode 175 and the gate insulation layer 140. In alternative exemplary embodiments, the ohmic contact members 161, 163 and 165 may be omitted.

Subsequently, a third insulation layer 180z may be formed to cover the data line 171 and the drain electrode 175.

A light blocking member 220 and color filters 230a, 230b and 230c may be formed on the third insulation layer 180z. A first insulation layer 180x may be formed on the color filters 230a, 230b and 230c and on the light blocking member 220.

It may be understood that FIG. 3A comprehensively illustrates the plurality of processes described above. Thus, configurations of the gate line 121 and the data line 171 may vary for each exemplary embodiment.

With reference to FIG. 3B, a common electrode 131 may be formed on the first insulation layer 180x. The common electrode 131 may be formed on an entire surface of the first substrate 110 as a single panel form. An aperture 138 may be defined in the common electrode 131 at a portion of the common electrode 131 overlapping a portion of the drain electrode 175.

With reference to FIG. 3C, a second insulation layer 180y may be formed on the common electrode 131. The second insulation layer 180y formed on the common electrode 131 extends into the aperture 138 defined in the common electrode 131 at the overlapped portion of the drain electrode 175. At the overlapped portion of the drain electrode 175 (e.g., at the aperture 138) are sequentially stacked from the first substrate 110, the third insulation layer 180z, the light blocking member 220, the first insulation layer 180x and the second insulation layer 180y.

With reference to FIG. 3D, a photoresist 50 may be coated on the second insulation layer 180y which is on the common electrode 131 and extends into the aperture 138 defined in the common electrode 131 at the overlapped portion of the drain electrode 175. The photoresist 50 formed at the overlapped portion of the drain electrode 175 may be subject to light (L with downward arrows) exposure using a mask 60.

With reference to FIG. 3E, the photoresist 50 subject to the light exposure may be developed, and thereby a photoresist pattern 51 may be formed.

With reference to FIG. 3F, through the use of the single one photoresist pattern 51, the third insulation layer 180z, the light blocking member 220, the first insulation layer 180x and the second insulation layer 180y may be etched to respectively form a third contact hole 183, a fourth contact hole 184, a first contact hole 181 and a second contact hole 182 in the third insulation layer 180z, the light blocking member 220, the first insulation layer 180x and the second insulation layer 180y. The third contact hole 183, the fourth contact hole 184, the first contact hole 181 and the second contact hole 182 may have the same shape and may expose the drain electrode 175. As a same shape, inclined surfaces of the third insulation layer 180z, the light blocking member 220, the first insulation layer 180x and the second insulation layer 180y at the third contact hole 183, the fourth contact hole 184, the first contact hole 181 and the second contact hole 182, may be coplanar with each other to form a continuous sidewall of a collective contact hole 185 defined by the third contact hole 183, the fourth contact hole 184, the first contact hole 181 and the second contact hole 182.

In an alternative exemplary embodiment, the third insulation layer 180z and the light blocking member 220 may be omitted, and the first insulation layer 180x may be formed between adjacent color filters among the color filters 230a, 230b, and 230c. Where the third insulation layer 180z and the light blocking member 220 are omitted and the first insulation layer 180x are formed between adjacent color filters among the color filters 230a, 230b, and 230c, the first contact hole 181 and the second contact hole 182 may be defined in the first insulation layer 180x and the second insulation layer 180y, respectively, using the photoresist pattern 51. Here, the first contact hole 181 and the second contact hole 182 may have the same shape and may expose the drain electrode 175. As a same shape, inclined surfaces of the first insulation layer 180x and the second insulation layer 180y at the first contact hole 181 and the second contact hole 182, may be coplanar with each other to form a continuous sidewall of a collective contact hole defined by the first contact hole 181 and the second contact hole 182.

As illustrated in FIG. 3G, a pixel electrode 191 may be provided to complete the lower display panel 100.

A first alignment layer 11 may be formed on the lower display panel 100. An upper display panel 200 may be prepared to include various layers on a second substrate 210 to complete the upper display panel 200. A second alignment layer 21 may be formed on the upper display panel 200. A liquid crystal layer 3 may be disposed between the lower display panel 100 and the upper display panel 200 and the two display panels 100 and 200 may be joined together to complete the LCD device.

As such, exemplary embodiments of a method of manufacturing the LCD device according to the invention simultaneously form the first contact hole 181 in the first insulation layer 180x covering the color filters 230a, 230b and 230c, and the second contact hole 182 in the second insulation layer 180y insulating the pixel electrode 191 from the common electrode 131, and thereby the process may be simplified and relatively high image resolution may be realized.

Where the third insulation layer 180z covering the data line 171 and the drain electrode 175, and the light blocking member 220 on the third insulation layer 180z are included in the lower display panel 100, exemplary embodiments of a method of manufacturing the LCD device according to the invention simultaneously form the third contact hole 183, the fourth contact hole 184, the first contact hole 181 and the second contact hole 182, which expose a portion of the drain electrode 175, may be defined in the third insulation layer 180z, the light blocking member 220, the first insulation layer 180x and the second insulation layer 180y, respectively, and thereby the process may be simplified and relatively high image resolution may be realized.

That is, compared to a conventional method of forming the first contact hole 181 in the first insulation layer 180x and the second contact hole 182 in the second insulation layer 180y separately, exemplary embodiments of the invention simultaneously form the first contact hole 181 and the second contact hole 182, and thereby a separate light exposure process of the first insulation layer 180x may be omitted. Accordingly, exemplary embodiments of a method of manufacturing the LCD device according to the invention simplify a process for forming the contact hole at which a field generating electrode contacts the switching element terminal and cost for performing the process may be reduced.

Further, since the first contact hole 181 in the first insulation layer 180x covering the color filters 230a, 230b and 230c, and the second contact hole 182 in the second insulation layer 180y insulating the pixel electrode 191 from the common electrode 131 are simultaneously formed, the first contact hole 181 and the second contact hole 182 may be correctly aligned with each other, and thus an issue of misalignment between the contact holes may be reduced or effectively prevented to realize relatively high image resolution.

Further, when the second contact hole 182 in the second insulation layer 180y is separately formed from the first contact hole 181 in the first insulation layer 180x such as by using a separate photoresist pattern, the photoresist for forming the second contact hole 182 may remain in the first contact hole 181 of the first insulation layer 180x which is formed in advance to underly the second insulation layer 180y. The residual photoresist within the first contact hole 181 may cause an image-quality defect. However, according to exemplary embodiments of a method of manufacturing the LCD device according to the invention, the first contact hole 181 and the second contact hole 182 are simultaneously formed with a single one photoresist pattern, and thus a photoresist may not remain within the first contact hole 181 such that relatively high image resolution may be realized.

From the foregoing, it will be appreciated that various exemplary embodiments in accordance with the present disclosure have been described herein for purposes of illustration, and that various modifications may be made without departing from the scope and spirit of the invention. Accordingly, the various exemplary embodiments disclosed herein are not intended to be limiting of the true scope and spirit of the present teachings. Various features of the above described and other embodiments can be mixed and matched in any manner, to produce further embodiments consistent with the invention.

What is claimed is:

1. A liquid crystal display device comprising:
a first display panel and a second display panel facing each other, and a liquid crystal layer between the first and second display panels facing each other;
the first display panel comprising:
a first substrate;
a gate line and a data line on the first substrate;
a thin film transistor connected to the gate line and the data line, a terminal of the thin film transistor exposed at a single contact hole;
a color filter on the thin film transistor;
a first insulation layer covering the color filter to dispose the color filter between the first insulation layer and the thin film transistor, the first insulation layer including defined therein a first contact hole which exposes the terminal of the thin film transistor at the single contact hole;
a common electrode on the first insulation layer covering the color filter;
a pixel electrode on the first insulation layer covering the color filter, the pixel electrode overlapping the common electrode; and
a second insulation layer between the pixel electrode and the common electrode, the second insulation layer including defined therein a second contact hole which exposes the terminal of the thin film transistor at the single contact hole,
wherein a shape of the first contact hole corresponds to a shape of the second contact hole to define the single contact hole at which the terminal of the thin film transistor is exposed.

2. The liquid crystal display device of claim 1, wherein
the terminal of the thin film transistor comprises a drain electrode, and
the first contact hole and the second contact hole at the single contact hole expose the drain electrode.

3. The liquid crystal display device of claim 2, wherein the pixel electrode contacts the drain electrode at the first contact hole and the second contact hole of which the shapes thereof correspond to define the single contact hole at which the terminal of the thin film transistor is exposed.

4. The liquid crystal display device of claim 1, wherein
an inclined surface of the first insulation layer at the first contact hole and an inclined surface of the second insulation layer at the second contact hole define the single contact hole at which the terminal of the thin film transistor is exposed, and
in a top plan view of the single contact hole, the second insulation layer at the single contact hole does not overlap the inclined surface of the first insulation layer at the first contact hole.

5. The liquid crystal display device of claim 1, further comprising a third insulation layer between the data line and the color filter, the third insulation layer including defined therein a third contact hole which exposes the terminal of the thin film transistor at the single contact hole.

6. The liquid crystal display device of claim 5, wherein
an inclined surface of the first insulation layer at the first contact hole, an inclined surface of the second insulation layer at the second contact hole and an inclined surface of the third insulation layer at the third contact hole define the single contact hole at which the terminal of the thin film transistor is exposed, and
in a top plan view of the single contact hole, the second insulation layer at the single contact hole does not overlap the inclined surface of the third insulation layer at the third contact hole.

7. A method of manufacturing a liquid crystal display device, the method comprising:
providing a first display panel and a second display panel to face each other, and
providing a liquid crystal layer between the first and second display panels facing each other;
the providing the first display panel comprising:
forming a gate line, a data line, and a thin film transistor which is connected to the gate line and the data line, on a first substrate, a terminal of the thin film transistor exposed at a single contact hole;
forming a color filter on the gate line, on the data line and on the thin film transistor;
forming a first insulation layer covering the color filter to dispose the color filter between the first insulation layer and the thin film transistor;
forming a common electrode on the first insulation layer covering the color filter;
forming a second insulation layer on the common electrode to dispose the common electrode between the first and second insulation layers; and
forming a first contact hole and a second contact hole respectively in the first insulation layer and in the second insulation layer, simultaneously, to define the single contact hole at which the terminal of the thin film transistor is exposed.

8. The method of claim 7, wherein the forming the first contact hole and the second contact hole comprises:
coating a photoresist on the second insulation layer which disposes the common electrode between the first and second insulation layers;
performing light exposure on the photoresist using a mask;
developing the light-exposed photoresist to form a photoresist pattern; and
simultaneously etching the first insulation layer and the second insulation layer between which is the common electrode, using the photoresist pattern to simultaneously form the first contact hole and the second contact hole in the first insulation layer and in the second insulation layer, respectively, to define the single contact hole at which the terminal of the thin film transistor is exposed.

9. The method of claim 8, further comprising forming a pixel electrode on the second insulation layer to dispose the second insulation layer between the pixel electrode and the common electrode.

10. The method of claim 9, wherein the terminal of the thin film transistor comprises a drain electrode.

11. The method of claim 10, wherein the first contact hole and the second contact hole at the single contact hole expose the drain electrode.

12. The method of claim 11, wherein the pixel electrode is connected to the drain electrode at the first contact hole and the second contact hole of which shapes thereof correspond to define the single contact hole at which the terminal of the thin film transistor is exposed.

13. A method of manufacturing a liquid crystal display device, the method comprising:
providing a first display panel and a second display panel to face each other, and
providing a liquid crystal layer between the first and second display panels facing each other;
the providing the first display panel comprising:
forming a gate line, a data line, and a thin film transistor which is connected to the gate line and the data line, on a first substrate, a terminal of the thin film transistor exposed at a single contact hole;
forming a third insulation layer on the gate line, the data line and the thin film transistor to dispose the gate line, the data line and the thin film transistor between the third insulation layer and the first substrate;
forming a color filter on the gate line, the data line, and the thin film transistor to dispose the third insulation layer between the color filter and the thin film transistor;
forming a first insulation layer covering the color filter to dispose the color filter between the first insulation layer and the third insulation layer;
forming a common electrode on the first insulation layer covering the color filter;
forming a second insulation layer on the common electrode to dispose the common electrode between the first and second insulation layers; and
forming a first contact hole, a second contact hole and a third contact hole respectively in the first insulation layer, in the second insulation layer and in the third insulation layer, simultaneously, to define the single contact hole at which the terminal of the thin film transistor is exposed.

14. The method of claim 13, wherein the forming the first contact hole, the second contact hole and the third contact hole comprises:
coating a photoresist on the second insulation layer which disposes the common electrode between the first and second insulation layers;
performing light exposure on the photoresist using a mask;
developing the light-exposed photoresist to form a photoresist pattern; and
simultaneously etching the first insulation layer, the second insulation layer and the third insulation layer using the photoresist pattern to simultaneously form the first contact hole, the second contact hole and the third contact hole in the first insulation layer, in second insulation layer in the third insulation layer, respectively to define the single contact hole at which the terminal of the thin film transistor is exposed.
